(19) United States
(12) Patent Application Publication
(10) Pub. No.: US 2013/0249071 A1
(43) Pub. Date: Sep. 26, 2013

(54) SEMICONDUCTOR DEVICE AND METHOD OF ASSEMBLING SAME

(71) Applicants: Jinzhong Yao, Tianjin (CN); Zhigang Bai, Tianjin (CN); Yuan Zang, Tianjin (CN)

(72) Inventors: Jinzhong Yao, Tianjin (CN); Zhigang Bai, Tianjin (CN); Yuan Zang, Tianjin (CN)

(21) Appl. No.: 13/854,140

(22) Filed: Apr. 1, 2013

Related U.S. Application Data
(63) Continuation-in-part of application No. 13/170,206, filed on Jun. 28, 2011.

(30) Foreign Application Priority Data
Sep. 11, 2012 (CN) 2012103368.9

(51) Int. Cl. H01L 23/495; H01L 21/56

(52) U.S. Cl. CPC H01L 23/495; H01L 21/565
USPC 257/676; 438/123

(57) ABSTRACT

A method of assembling a semiconductor device includes providing a lead frame having a die pad and a fame member with lead fingers that surround the die pad. The lead fingers have distal ends connected to the frame member and proximal ends near the die pad. A die is attached to the die pad and die connection pads are electrically connected to the proximal ends of the lead fingers with bond wires. The die, bond wires, and part of the lead fingers are encapsulated with an encapsulant. The encapsulating process includes separating the lead fingers into first and second sets of lead fingers. The proximal ends of the first set lie in a first plane and the proximal ends of the second set lie in a second plane that is spaced and maintained from the first plane solely by the encapsulation material.

### CROSS-REFERENCE TO RELATED APPLICATION

This application is a continuation-in-part of currently pending U.S. patent application Ser. No. 13/170,206 filed on Jun. 28, 2011, and assigned to Freescale Semiconductor, Inc.

### BACKGROUND OF THE INVENTION

The present invention relates to semiconductor packaging and, more particularly, to semiconductor packages with relatively high lead finger counts.

A semiconductor die is a small device formed on a semiconductor wafer, such as a silicon wafer. Such a die is typically cut from the wafer and packaged in a semiconductor package using a lead frame. The lead frame is a metal frame, usually of copper or nickel alloy, that supports the die and provides external electrical connections for the packaged die. The lead frame usually includes a flag (die pad), and associated proximal lead fingers (leads). The semiconductor die is attached to the flag and bond pads on the die are electrically connected to the lead fingers of the lead frame with bond wires. The die and bond wires are encapsulated with a protective encapsulation material to form a semiconductor device or package. The lead fingers either project outwardly from the encapsulation or are at least flush with the encapsulation so they can be used as terminals, allowing the semiconductor device to be electrically connected directly to other devices or to a printed circuit board (PCB).

Semiconductor devices are being assembled with an increased functionality to package pin count (external terminal or I/O count). This is partly because of improved silicon die fabrication techniques that allow die size reductions, or more circuitry on per die. However, the number of leads or external connections is limited by the size of the package and the pitch of or spacing between the lead fingers. In this regard, a reduced lead finger pitch generally increases the likelihood of short circuit faults, which reduces yield and increases manufacturing costs.

One solution that may overcome or alleviate problems associated with reduced lead finger pitch is to space adjacent lead fingers in different planes by the use of an insulating spacer. This spacer, although beneficial, requires relatively careful and accurate placement between selected leads before the bond pads are electrically connected to the leads with the bond wires. It would therefore be useful if adjacent lead fingers could be spaced in different planes without the need of the abovementioned insulating spacer.

### BRIEF DESCRIPTION OF THE DRAWINGS

The invention, together with objects and advantages thereof, may best be understood by reference to the following description of preferred embodiments together with the accompanying drawings in which:

FIG. 1 is a plan view of an electrically conductive lead frame sheet in accordance with a preferred embodiment of the present invention;

FIG. 2 is a plan view of partially assembled packages, formed on the electrically conductive lead frame sheet of FIG. 1, each including an attached semiconductor die in accordance with a preferred embodiment of the present invention;

FIG. 3 is a plan view of partially assembled electrically coupled packages, formed on the electrically conductive lead frame sheet of FIG. 1, with contact pads of each semiconductor die electrically coupled to lead fingers of the lead frame sheet in accordance with a preferred embodiment of the present invention;

FIG. 4 is a cross-sectional view of one of the packages of FIG. 3, through 3-3′, immediately before encapsulating the semiconductor die with an encapsulation material;

FIG. 5 is a cross-sectional view of one of the packages of FIG. 3, through 3-3′, immediately after encapsulating the semiconductor die with an encapsulation material, in accordance with a preferred embodiment of the present invention;

FIG. 6 is a plan view of encapsulated semiconductor packages on the conductive lead frame sheet of FIG. 1, after encapsulation in accordance with a preferred embodiment of the present invention;

FIG. 7 is a plan view of a semiconductor package after removal from the conductive lead frame sheet of FIG. 1, in accordance with a preferred embodiment of the present invention;

FIG. 8 is a cross-sectional view of the semiconductor package of FIG. 7, through 7-7′, in accordance with a preferred embodiment of the present invention;

FIG. 9 is a cross-sectional view of the semiconductor package of FIG. 7, through 7-7′, after bending lead fingers in accordance with a preferred embodiment of the present invention;

FIG. 10 is a side view of the semiconductor package of FIG. 9 in accordance with a preferred embodiment of the present invention;

FIG. 11 is an enlarged view of part of the semiconductor package of FIG. 9, in accordance with a preferred embodiment of the present invention;

FIG. 12 is a plan view of an electrically conductive lead frame sheet in accordance with another preferred embodiment of the present invention;

FIG. 13 is a side view of a semiconductor package in accordance with another preferred embodiment of the present invention;

FIG. 14 is a cross-sectional view of part of a fine pitch leaded package immediately before encapsulating with an encapsulation material in accordance with a preferred embodiment of the present invention;

FIG. 15 is the fine pitch leaded package of FIG. 14 immediately after encapsulating with an encapsulation material, in accordance with a preferred embodiment of the present invention; and

FIG. 16 is a flow chart illustrating a method of packaging a semiconductor die in accordance with a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, method steps and structures that comprises a list of elements does not include only those elements but may include other elements not expressly listed or inherent to such module, circuit, steps or device components. An element or step proceeded by “comprises” does not, without more constraints, preclude the existence of additional identical elements or steps that comprises the element or step.

Certain features in the drawings have been enlarged for ease of illustration and the drawings and the elements thereof are not necessarily in proper proportion. Further, the invention is shown embodied in a quad flat pack (QFP) type package. However, those of ordinary skill in the art will readily understand the details of the invention and that the invention is applicable to all leaded package types and their variations.

In one embodiment, the present invention provides a method of assembling a semiconductor device. The method includes providing an electrically conductive lead frame sheet with at least one die pad, a frame member surrounding the die pad and a plurality of lead fingers. The lead fingers extend from the frame member towards the die pad, and wherein the lead fingers each have a distal end connected to the frame member and a proximal end near the die pad. The method includes attaching a semiconductor die to the die pad and electrically coupling contact pads on the semiconductor die with respective proximal ends of the lead fingers. The method further includes encapsulating at least the die, the die pad and the proximal ends of the lead fingers with an encapsulation material. The encapsulating process includes separating the lead fingers into a first set and second set of lead fingers, and wherein the proximal ends of the first set of lead fingers lie in a first plane and the proximal ends of the second set of lead fingers lie in a second plane that is spaced and maintained from the first plane solely by the encapsulation material.

In another embodiment, the present invention provides a semiconductor device comprising a die pad and a first set of lead fingers that are spaced from and project outwardly from the die pad, wherein the lead fingers have proximal ends close to the die pad and distal ends farther from the die pad, and wherein the proximal ends of the first set of lead fingers lie in a first plane. A second set of lead fingers are spaced from and project outwardly from the die pad. The lead fingers of the second set have proximal ends close to the die pad and distal ends farther from the die pad. The proximal ends of the lead fingers of the second set lie in a second plane that is spaced from the first plane. A semiconductor die attached to a surface of the die pad, and bonding pads of the semiconductor die are electrically coupled to respective proximal ends of the first and second sets of lead fingers with bond wires. An encapsulation material covers the bond wires, die, and the proximal ends of the first and second sets of lead fingers. The encapsulation material is disposed in a space between the proximal ends of the first and second sets of lead fingers and maintains the first set of lead fingers in the first plane and second set of lead fingers in the second plane. The distal ends of the first and second sets of lead fingers project outwardly from the encapsulation material and allow for external electrical connection with the semiconductor die.

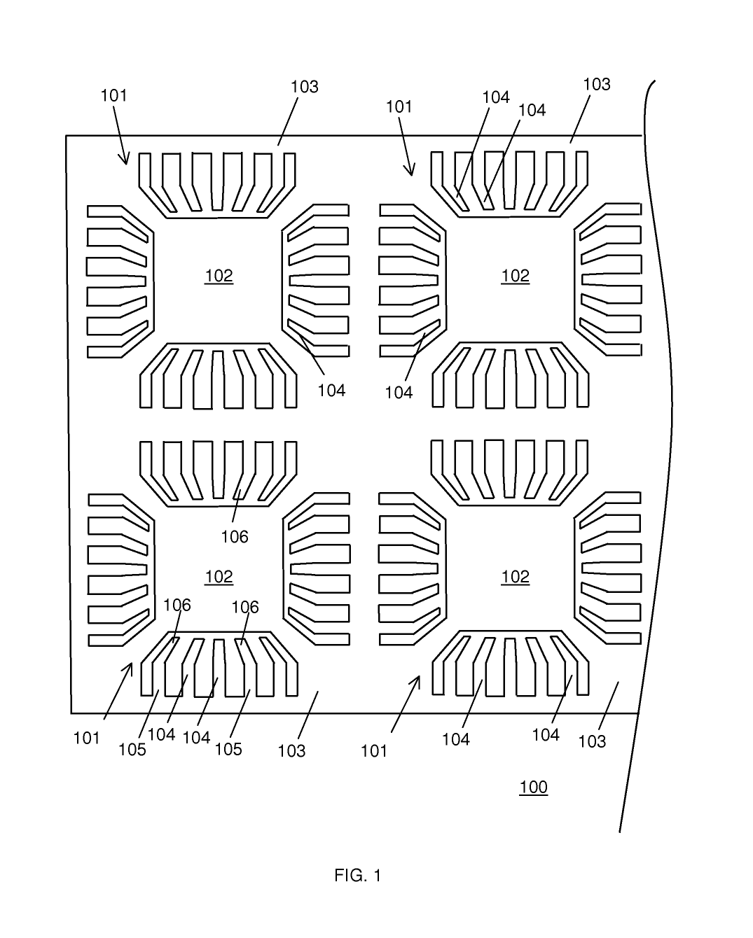

Referring now to FIG. 1, a plan view of an electrically conductive lead frame sheet 100 in accordance with a preferred embodiment of the present invention is shown. The lead frame sheet 100 has a plurality of lead frames 101, each comprising a die pad 102, a frame member 103 surrounding the die pad 102 and a plurality of lead fingers 104. The lead fingers 104 extend from the frame member 103 towards the die pad 102, and lead fingers have a distal end 105 connected to the frame member and a proximal end 106 near the die pad 102.

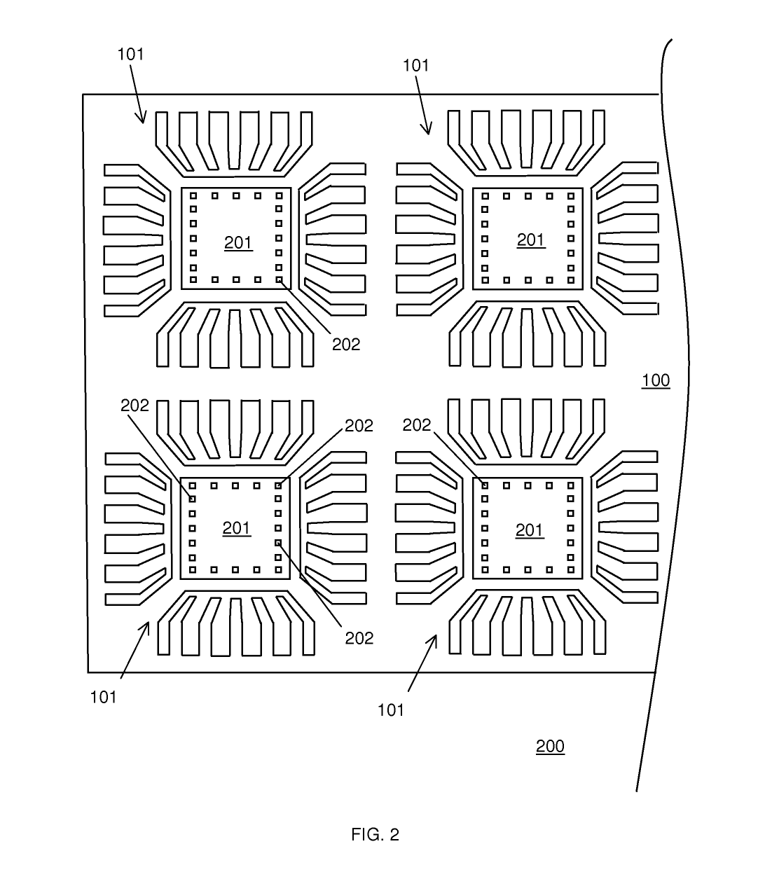

FIG. 2 is a plan view of partially assembled devices 200, formed on the electrically conductive lead frame sheet 100, each including an attached semiconductor die 201 in accordance with a preferred embodiment of the present invention. Typically, the semiconductor die 201 is attached to the die pad 102 with a bonding agent (not shown) as is known by those of skill in the art. Also, as various size semiconductor dice are known, it is understood that the size and shape of the die pad 102 will depend on the particular semiconductor die 201 being packaged. The semiconductor die 201 has contact pads 202 (that can be circuit electrodes) that are input, output or power supply nodes. The contact pads 202 are disposed on an upper or active surface of the semiconductor die 201.

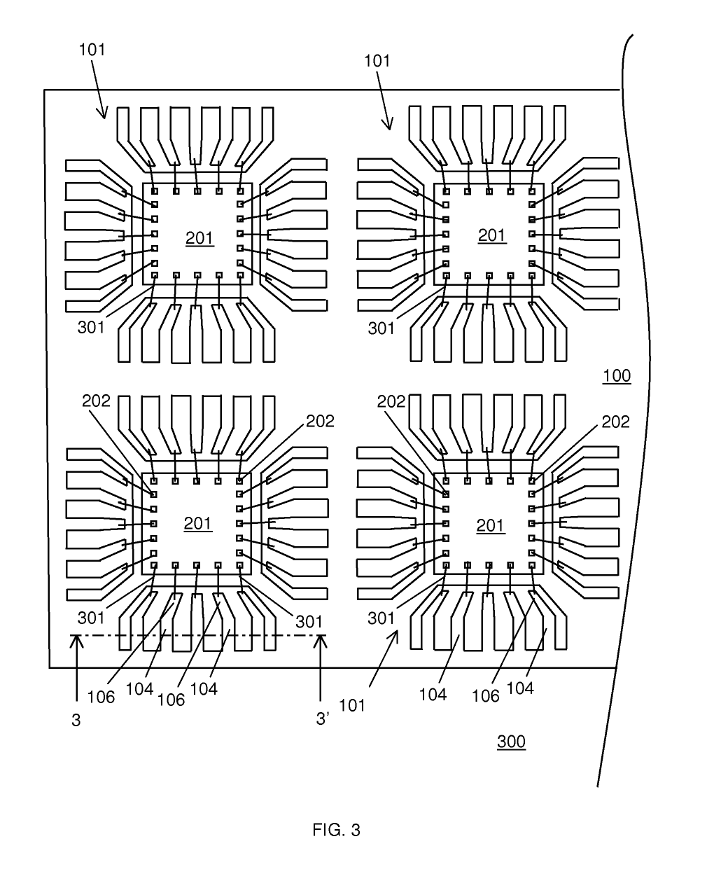

Referring to FIG. 3, a plan view of partially assembled electrically coupled devices 300, formed on the electrically conductive lead frame sheet 100, with the contact pads 202 of each semiconductor die 201 electrically coupled to lead fingers 104 of the lead frame sheet 100 in accordance with a preferred embodiment of the present invention is shown. The contact pads 202 are electrically coupled (connected), with bond wires 301, with respective proximal ends 106 of the lead fingers 104.

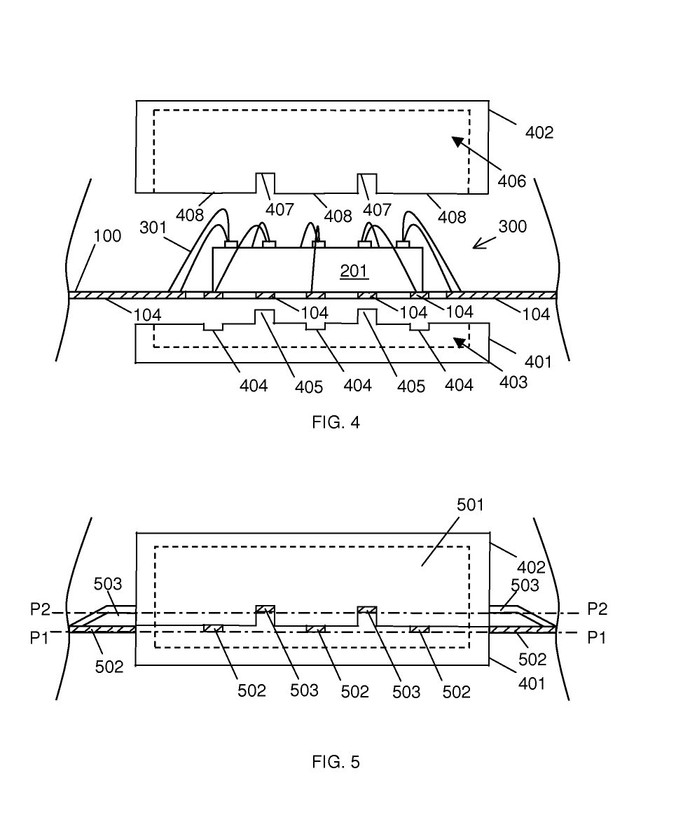

FIG. 4 is a cross-sectional view of one of the partially assembled electrically coupled devices 300, through 3-3′, immediately before encapsulating the semiconductor die 210 with an encapsulation material. As shown, there is a two-part mold comprising a lower mold 401 aligned with an upper mold 402. The lower mold 401 has a lower mold chamber 403, lower mold lead finger slots 404 and lower mold lead finger anvils 405. The upper mold 402 has an upper mold chamber 406, upper mold lead finger slots 407 and upper mold lead finger anvils 408. The upper mold lead finger slots 407 are aligned with respective lower mold lead finger anvils 405 and each of the lower mold lead finger slots 404 is aligned with a respective one of the upper mold lead finger anvils 408.

Referring to FIG. 5, there is illustrated a cross sectional view of the partially assembled electrically coupled device 300, through 3-3′, immediately after encapsulating the semiconductor die 201 with an encapsulation material 501, in accordance with a preferred embodiment of the present invention. The encapsulating material 501 is a water resistant electrically insulating molding compound that is injection molded into the upper and lower mold chambers 403, 406. The encapsulating material 501 is injection molded during a process of encapsulating (injection molding) which includes separating the lead fingers 104 into a first set of lead fingers 502 and a second set of lead fingers 503.

The separating is performed by a co-acting interrelationship of: (a) the lower mold lead finger slots 404 and upper mold lead finger anvils 408, which capture and retain the first set of lead fingers 502 in a first plane P1; and (b) the lower mold lead finger anvils 405 and upper mold lead finger slots 407 which capture and bend the second set of lead fingers 503 so that their proximal ends 106 lie in a second plane P2. More specifically, the proximal ends 106 of the first set of lead fingers 502 lie in the first plane P1 and the proximal ends 106 of the second set of lead fingers 503 lie in the second plane P2. Once the encapsulation material 501 sets, the molds 401,402 are removed and the proximal ends 106 of the first and second set of lead fingers 502, 503 are spaced and maintained in their respective planes P1, P2 solely by the encapsulation material 501.

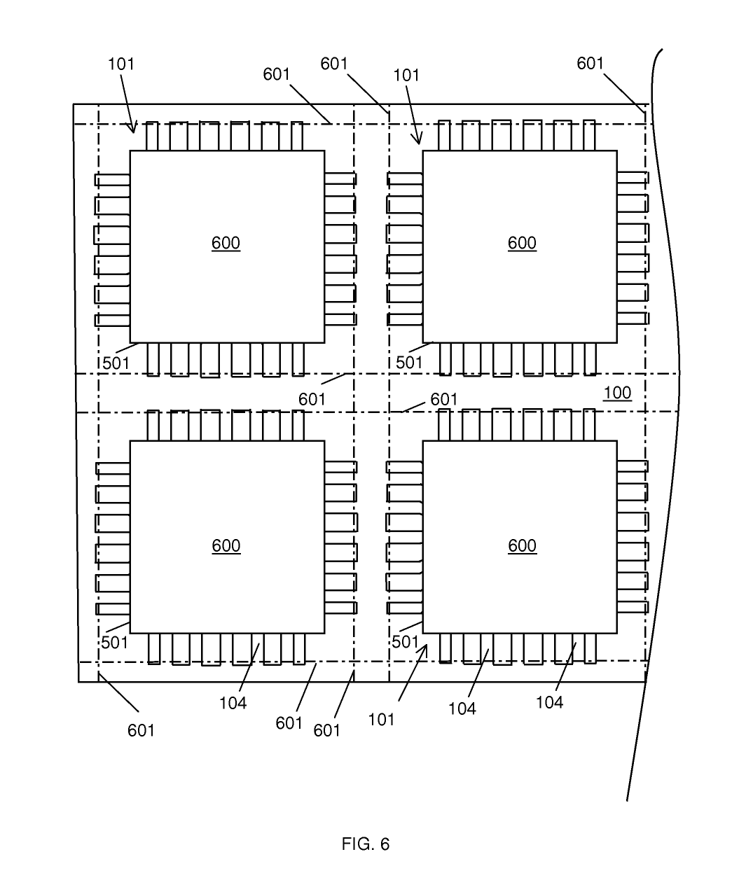

Referring to FIG. 6, there is illustrated a plan view of encapsulated semiconductor devices 600 on the conductive lead frame sheet 100 after encapsulation in accordance with a preferred embodiment of the present invention. As shown, the encapsulating material 501 has been molded to the conductive lead frame sheet 100 thereby encapsulating each semiconductor die 201, each die pad 102, the bond wires 301 and the proximal ends 106 of the lead fingers 104. Each one of the encapsulated semiconductor devices 600 is removed (singulated) from the lead frame sheet 100 by a cutting or punching process along singulation lines 601.

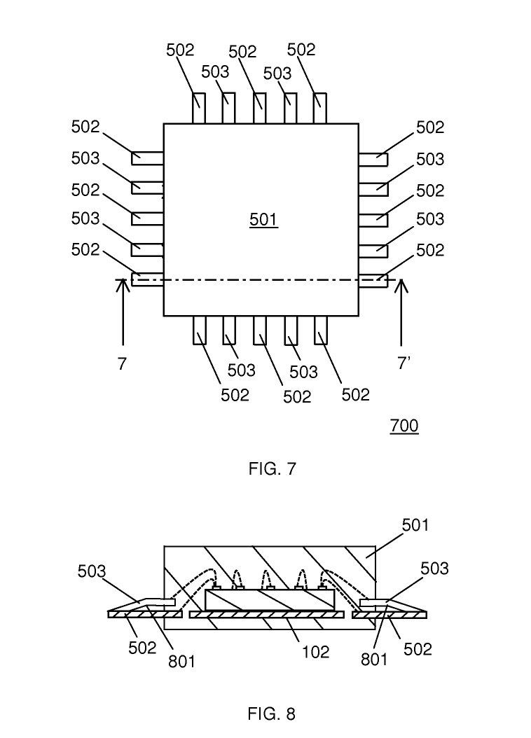

In FIG. 7, there is illustrated a plan view of a semiconductor device 700 after removal from the conductive lead frame sheet of FIG. 1, in accordance with a preferred embodiment of the present invention. As shown, the first set of lead fingers 502 are interleaved with the second set of lead fingers 503. More specifically, members of the first set of lead fingers 502 are in an alternating arrangement with members of the second set of lead fingers 503.

Referring to FIG. 8, there is illustrated a cross sectional view of the semiconductor device 700, through 7-7′, in accordance with a preferred embodiment of the present invention. The proximal ends 106 of the first set of lead fingers 502 are spaced from and lie in a different plane to that of the proximal ends 106 of the second set of lead fingers 503. The first set of lead fingers 502 lie in the same plane as the die pad 102, and each member of the second set of lead fingers 503 has an intermediate bend 801 caused by the interaction of the anvils 405 and slots 407 during the process of molding.

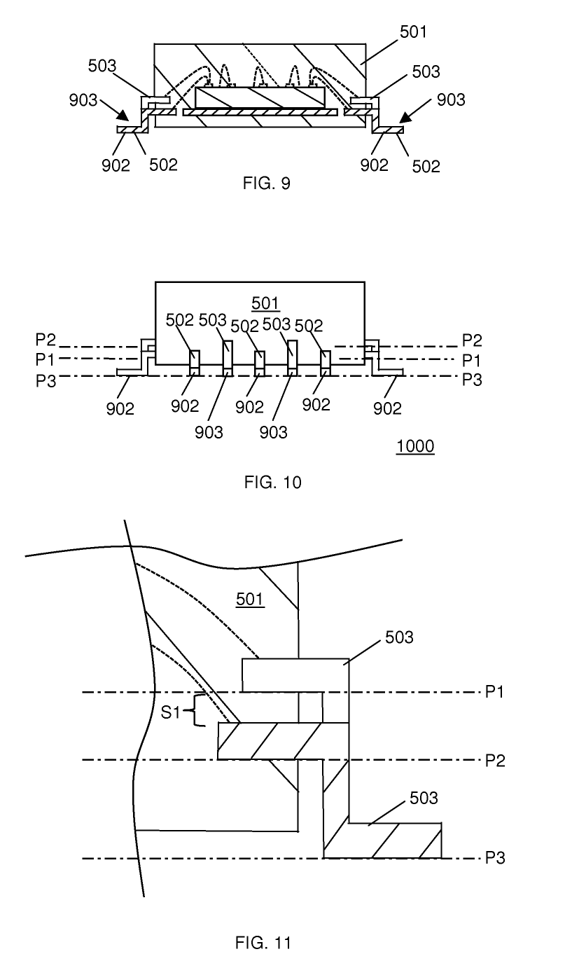

FIG. 9 is a cross-sectional view of the semiconductor device 700, through 7-7′, after bending lead fingers 104 of the semiconductor device 700 in accordance with a preferred embodiment of the present invention. More specifically, as shown the first set of lead fingers 502 are bent so that they have mounting feet 902 and the second set of lead fingers 503 are also bent so that they also have mounting feet 903.

Referring to FIG. 10, a side view of an assembled and formed semiconductor device 1000 in accordance with a preferred embodiment of the present invention is shown. The semiconductor device 1000 is the package as illustrated in FIG. 9 and in use it is mounted to a circuit board or the like by the mounting feet 902, 903. As will be apparent to a person skilled in the art, the projecting first and second sets lead fingers 502, 503 have undergone trim and form operations such that a Quad Flat type package is formed. The mounting feet 902, 903 (distal ends 105) lie in a third plane P3 that is spaced from the first and second planes P1, P2. Typically, and as illustrated, the first and second planes P1, P2 are parallel to each other and the third plane P3 is also parallel to both the first and second planes P1, P2.

The first set of lead fingers 502 are spaced from and project outwardly from the die pad 102 and the lead fingers have their proximal ends 106 close to the die pad 102 and their distal ends 105 are farther from the die pad 102. Also, the proximal ends of the first set of lead 502 fingers lie in the first plane P1 and second set of lead fingers 503 are spaced from and project outwardly from the die pad 102. The second set of lead fingers 503 have proximal ends 106 close to the die pad 102 and distal ends 105 farther from the die pad 102. The proximal ends 106 of the second set of lead fingers 503 lie in the second plane P2 that is spaced from the first plane P1.

FIG. 11 is an enlarged view of part of the semiconductor device of FIG. 9. As illustrated, there is a space S1 between planes P1 and P2. This space S1 is maintained solely by the encapsulating material 501 which acts as a spacer, electrical insulator and water resistant seal for the package.

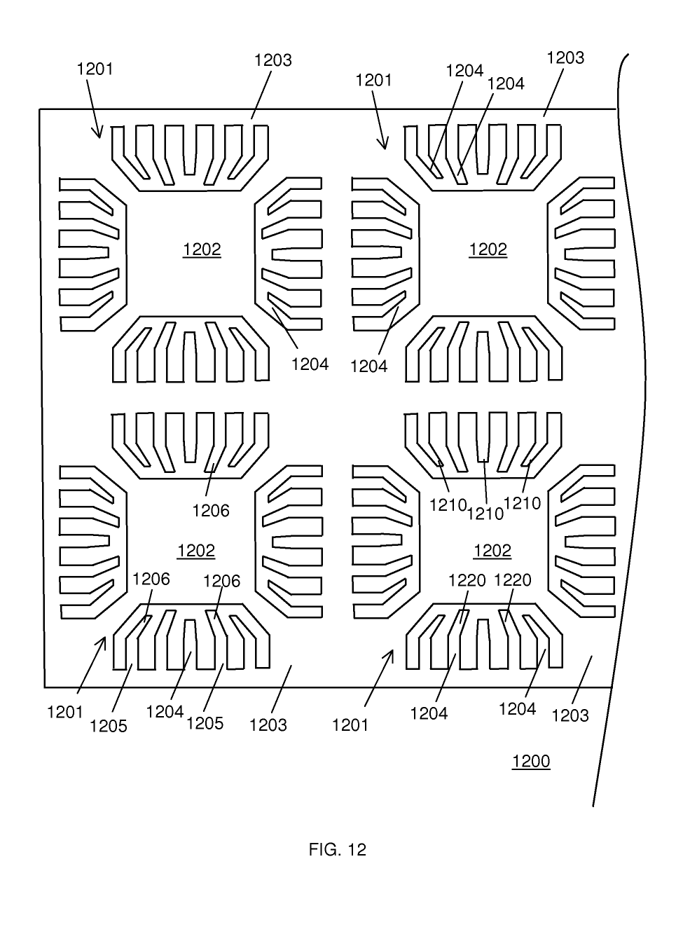

Referring to FIG. 12, a plan view of an electrically conductive lead frame sheet 1200 in accordance with another preferred embodiment of the present invention is shown. In this embodiment the lead frame sheet 1200 has a plurality of lead frames 1201, each comprising a die pad 1202, a frame member 1203 surrounding the die pad 1202 and a plurality of lead fingers 1204. The lead fingers 1204 extend from the frame member 1203 towards the die pad 1202, and lead fingers have a distal end 1205 connected to the frame member and a proximal end 106 near the die pad 1202. The lead frame sheet 1200 can be used to form the semiconductor package 1000 in which each member of a second set of the lead fingers 1220 is longer than each member of the first set of lead fingers 1210. This difference in length may be beneficial as it allows for a the provision of a greater space S1 between the planes P1, P2 since the second set of the lead fingers 1220 can almost touch the die pad 1202 before they are bent to lie in the second plane P2.

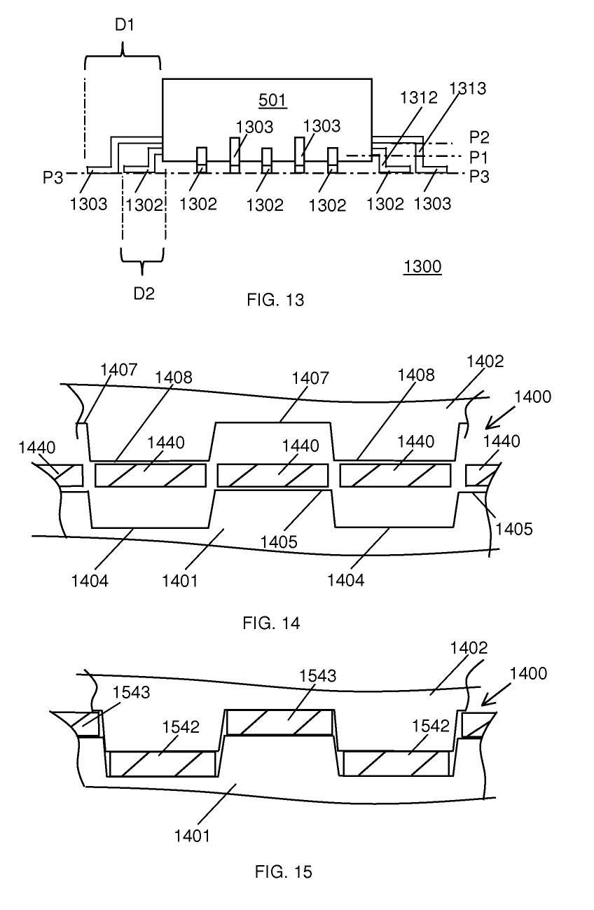

FIG. 13 is a side view of an assembled and formed semiconductor device 1300 in accordance with another preferred embodiment of the present invention. The semiconductor device 1300 is similar to semiconductor package 1300 and is manufactured and package in a similar way to that of package 1000. Accordingly, to avoid repetition, only the differences will be described.

As illustrated, the semiconductor device 1300 has a first set of lead fingers 1302 and a second set of lead fingers 1303. The semiconductor device 1300 may be formed, for example, from the conductive lead frame sheet 100 or conductive lead frame sheet 1200. In this embodiment the second set of lead fingers 1303 are longer than the first set of lead fingers 1302 and therefore lead fingers 1303 extend out of the encapsulating material 501 significantly further than the lead fingers 1302. More specifically, the distal ends the second set of lead fingers 1303 are space further away from the encapsulation material 501 than the distal ends of the first set of lead fingers 1302. In this regard, the distal ends the second set of lead fingers 1303 are spaced from the encapsulation material 501 by a distance D1, and the distal ends of the first set of lead fingers 1302 are spaced from the encapsulation material 501 by a distance D2. The different lengths or distances of D1 and D2 are the result of trim and forming as will be apparent to a person skilled in the art.

As shown, an upright section 1312 of the first set of lead fingers 1302 is in a different plane to that of an upright section 1313 of the second set of lead fingers 1303. Advantageously, this preferred embodiment can allow for finer lead pitches especially when solder circuit board shorting can be an issue due to the proximity of adjacent lead finger distal ends.

FIG. 14 is a cross-sectional view of part of a fine pitch leaded device 1400 immediately before encapsulating with an encapsulation material. The fine pitch leaded device 1400 is essentially the same as one of the device 300 with the exception that lead pitch of lead fingers 1440 in the package 1400 is much finer. That is, the spacing between the leads is smaller. As shown, there is a two-part mold comprising a lower mold 1401 aligned with an upper mold 1402. The lower mold 1401 has a lower mold chamber (not illustrated) and lower mold lead finger slots 1404 and lower mold lead finger anvils 1405. The upper mold 1402 has an upper mold chamber (not illustrated), upper mold lead finger slots 1407 and upper mold lead finger anvils 1408. The upper mold lead finger slots 1407 are aligned with respective lower mold lead finger anvils 1405 and each of the lower mold lead finger slots 1404 is aligned with a respective one of the upper mold lead finger anvils 1408.

Referring to FIG. 15, there is illustrated the fine pitch leaded device 1400 immediately after encapsulating with an encapsulation material (not illustrated), in accordance with a preferred embodiment of the present invention. The encapsulating material is a water resistant electrically insulating molding compound that is injection molded into the upper and lower mold chambers. The encapsulating material is injection molded during a process of encapsulating (injection molding), which includes separating the lead fingers 1440 into a first set of lead fingers 1542 and a second set of lead fingers 1543.

As above, the separating is performed by a co-acting interrelationship of: (a) the lower mold lead finger slots 1404 and upper mold lead finger anvils 1408 which capture and retain the first set of lead fingers 1542 in the first plane P1; and (b) the lower mold lead finger anvils 1405 and upper mold lead finger slots 1407 which capture and bend the second set of lead fingers 1543 so that their proximal ends lie in the second plane P2.

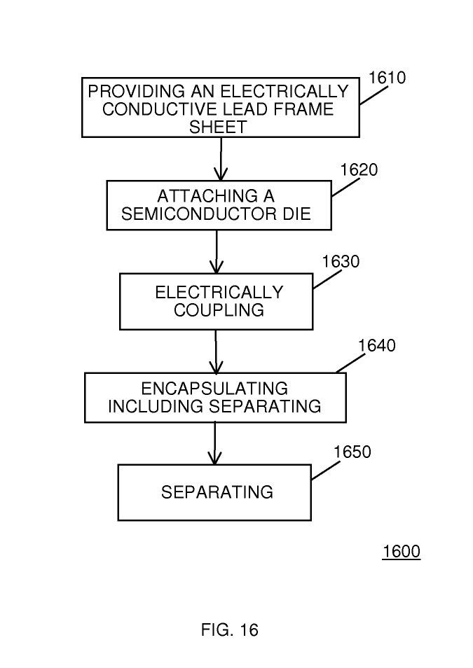

Referring now to FIG. 16, a flow chart of a method 1600 of packaging a semiconductor die in accordance with a preferred embodiment of the present invention is shown. The method 1600 will be described, where necessary, with reference to FIGS. 1 to 11, however, the method is not limited to the specific embodiments of FIGS. 1 to 11 as will be apparent to a person skilled in the art. The method 1600 includes, at step 1610, providing the electrically conductive lead frame sheet 100, however, the sheet 1600 may also be provided as one alternative. At step 1620 there is performed attaching each semiconductor die 201 to a respective die pad 102. At step 1630 there is performed a process of electrically coupling the contact pads 202 on each semiconductor die 201 with respective proximal ends 106 of the lead fingers 104. This electrically coupling is typically performed by a conventional wire bonding process. Next, at step 1640, the method 1600 performs encapsulating at least the die 201, the die pad 102 and the proximal ends 106 of the lead fingers 104 with the encapsulation material 501. The process of encapsulating includes separating the lead fingers into the first and second sets of lead fingers 502, 503. Also, after separating, the proximal ends 106 of the first set of lead fingers 502 lie in the first plane P1 and the proximal ends 106 of the second set of lead fingers 503 lie in a second plane P2 that is spaced and maintained from the first plane P1 solely by the encapsulation material 501.

The encapsulating is performed by injection molding using the two-part mold comprising the lower mold 401 and upper mold 402. In this regard, the proximal ends 106 of the lead fingers are seated in the two-part mold, and slots and anvils of the mold capture and bend the proximal ends 106 of the second set of lead fingers 503 so that they lie in the second plane P2.

At step 1650, separating the lead fingers 104 from the frame member 103 is performed to provide the semiconductor device 700. The separating is performed during trim and form in which the distal ends 105 of the first and second sets of lead fingers 502, 503 are bent to have so that they have mounting feet 902, 903 that lie in the third plane P3. Thus, as will be apparent to a person skilled in the art, after completion of the method 1600 there will be formed numerous semiconductor packages 1000 having mounting feet 902, 903 that lie in the third plane P3 which is spaced from the first and second planes P1,P2. The method 1600 can also be advantageously used to provide the semiconductor package 1300, or similar packages, as will be apparent to a person skilled in the art.

In the embodiments shown in the drawings the second plane P2 lies above or over the first plane P1. However, this is not a requirement as in alternative embodiments the second plane P2 could lie below or beneath the first plane P1. Furthermore, it should also be understood by those of skill in the art that the lead fingers 104 may be trimmed and/or formed, for example such that the first and second sets of lead fingers 502, 503 need not be bent such as in the illustrated gull-wing shape, and could have other shapes.

Although the illustrations show the die pad 102 being completely encapsulated with the encapsulation material 501, the die pad 102 could have an exposed bottom surface, in which case the encapsulation material 501 would cover only the sides and portions of the top surface of the die pad 102 not already covered by the semiconductor die 201.

Advantageously, the proximal ends 106 of the lead fingers 104 are disposed in spaced planes P1, P2 spaced apart by space S1. The proximal ends 106 are maintained in their relevant spaced planes by the encapsulating material 501. Accordingly, the present invention potentially reduces or alleviates the possibility of short circuit faults between adjacent lead fingers because the gap (pitch) between such lead fingers would otherwise be relatively narrow. Also, the present invention provides for spacing the proximal ends 106 of the lead fingers 104 in planes P1, P2 without the need for accurate placement of an additional spacer component between selected leads fingers 104.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A method of packaging a semiconductor die, the method comprising:
providing an electrically conductive lead frame sheet having at least one die pad, a frame member surrounding the die pad, and a plurality of lead fingers, wherein the lead fingers extend from the frame member towards the die pad, and wherein the lead fingers each have a distal end connected to the frame member and a proximal end near the die pad;
attaching a semiconductor die to the die pad;
electrically connecting contact pads on the semiconductor die with respective proximal ends of the lead fingers; and
encapsulating at least the die, the die pad and the proximal ends of the lead fingers with an encapsulation material, wherein the encapsulating includes separating the lead fingers into first and second sets of lead fingers, and wherein the proximal ends of the first set of lead fingers lie in a first plane and the proximal ends of the second set of lead fingers lie in a second plane that is spaced and maintained from the first plane solely by the encapsulation material.

2. The method of packaging a semiconductor die of claim 1, wherein the first and second sets of lead fingers are interleaved.

3. The method of packaging a semiconductor die of claim 2, wherein members of the first set of lead fingers are in an alternating arrangement with members of the second set of lead fingers.

4. The method of packaging a semiconductor die of claim 1, wherein the encapsulating is performed by molding.

5. The method of packaging a semiconductor die of claim 4, wherein the molding is performed by a mold within which the proximal ends of the lead fingers are seated, and wherein the mold has slots and anvils that capture and bend the proximal ends of the second set of lead fingers so that the proximal ends of the second set of lead fingers lie in the second plane.

6. The method of packaging a semiconductor die of claim 1, further comprising separating the lead fingers from the frame member.

7. The method of packaging a semiconductor die of claim 6, further comprising bending the lead fingers so that the distal ends of the lead fingers lie in a third plane that is spaced from the first and second planes.

8. The method of packaging a semiconductor die of claim 7, wherein the first and second planes are parallel to each other.

9. The method of packaging a semiconductor die of claim 8, wherein the third plane is parallel to the first plane.

10. The method of packaging a semiconductor die of claim 1, wherein each member of the second set of lead fingers is longer than each member of the first set of lead fingers.

11. The method of packaging a semiconductor die of claim 1, wherein the distal ends the second set of lead fingers are spaced further away from the encapsulation material than the distal ends of the first set of lead fingers.

12. A semiconductor device, comprising:
a die pad;
a first set of lead fingers that are spaced from and project outwardly from the die pad, wherein the lead fingers have proximal ends close to the die pad and distal ends farther from the die pad, and wherein the proximal ends of the first set of lead fingers lie in a first plane;
a second set of lead fingers that are spaced from and project outwardly from the die pad, wherein the second set of lead fingers have proximal ends close to the die pad and distal ends farther from the die pad, and wherein the proximal ends of the second set of lead fingers lie in a second plane that is spaced from the first plane;
a semiconductor die attached to the die pad, wherein bonding pads on the semiconductor die are electrically coupled to respective said proximal ends of the first and second sets of lead fingers with bond wires; and
an encapsulation material covering the bond wires, semiconductor die and the proximal ends of the first and second sets of lead fingers, wherein the encapsulation material is disposed in a space between the proximal ends of the first and second sets of lead fingers such that the encapsulation material maintains the first set of lead fingers in the first plane and the second set of lead fingers in the second plane, and wherein the distal ends of the first and second sets of lead fingers project outwardly from the encapsulation material and allow for external electrical connection with the semiconductor die.

13. The semiconductor device of claim 12, wherein the first and second sets of lead fingers are interleaved.

14. The semiconductor device of claim 13, wherein members of the first set of lead fingers are in an alternating arrangement with members of the second set of lead fingers.

15. The semiconductor device of claim 12, wherein the encapsulation material is a molding compound and wherein the proximal ends of the second set of lead fingers were positioned to lie in the second plane when the lead fingers are covered with the encapsulation material.

16. The semiconductor device of claim 12, wherein the first and second planes are parallel to each other.

17. The semiconductor device of claim 12, wherein the distal ends of the lead fingers lie in a third plane that is spaced from the first and second planes.

18. The semiconductor device of claim 17, wherein the third plane is parallel to the first plane.

19. The semiconductor device of claim 18, wherein the third plane is parallel to the first and second planes.

20. The semiconductor device of claim 12, wherein the distal ends of the second set of lead fingers extend further away from the encapsulation material than the distal ends of the first set of lead fingers.
